(19) United States
(12) Patent Application Publication
(10) Pub. No.: US 2025/0324680 A1
(43) Pub. Date: Oct. 16, 2025

(54) GATE TRENCH POWER SEMICONDUCTOR DEVICES HAVING ENHANCED AVALANCHE ROBUSTNESS AND METHODS OF FORMING SUCH DEVICES

(71) Applicant: Wolfspeed, Inc., Durham, NC (US)

(72) Inventors: Rahul R. Potera, Apex, NC (US); Naeem Islam, Morrisville, NC (US)

(21) Appl. No.: 18/633,618

(22) Filed: Apr. 12, 2024

(51) Int. Cl. H01L 29/06; H01L 29/16; H01L 29/78

(52) U.S. Cl. CPC H10D 62/109; H10D 30/668; H10D 62/127; H10D 62/8325

(57) ABSTRACT

A semiconductor device includes a semiconductor layer structure including a drift region, a gate trench in the semiconductor layer structure extending in a first direction parallel to an upper surface of the semiconductor layer structure, and a trench shielding region in the semiconductor layer structure beneath a bottom of the gate trench. The trench shielding region includes a first portion having a uniform width in a third direction, parallel to the upper surface of the semiconductor layer structure and perpendicular to the first direction, at a first depth in a second direction perpendicular to the upper surface of the semiconductor layer structure and a second portion having a non-uniform width in the third direction at the first depth in the second direction.

### FIELD

The present invention relates generally to power semiconductor devices and, more particularly, to power semiconductor devices having gate trenches and to methods of fabricating such devices.

### BACKGROUND

A metal-oxide-semiconductor field-effect transistor (“MOSFET”) is a well-known type of semiconductor transistor that may be used as a switch. A MOSFET is a three terminal device that has gate, drain and source terminals and a semiconductor body. The semiconductor body is referred to herein as a “semiconductor layer structure” and may include one or more semiconductor layers/regions. A source region and a drain region are formed in the semiconductor layer structure that are separated by a channel region. A gate electrode (which may act as the gate terminal or be electrically connected to the gate terminal) is disposed adjacent the channel region and separated from the channel region by a thin layer of insulating material (e.g., oxide), generally referred to as a gate oxide layer. Other non-oxide gate dielectric layers may be used in certain applications in place of the gate oxide layer. It will be appreciated that the techniques according to embodiments of the present invention that are described herein are equally applicable to devices having gate dielectric layers formed with materials other than oxides.

The MOSFET may be turned on or off by applying a bias voltage to the gate electrode that is above or below a threshold voltage of the MOSFET. When a MOSFET is turned on (i.e., it is in its “on-state”) and there is a positive voltage difference between the source and drain terminals, current will be conducted through the channel region between the source and drain regions. When the bias voltage is reduced below the threshold voltage, the current ceases to flow through the channel region.

An n-type MOSFET has source and drain regions that have n-type (electron) conductivity and a channel region that has p-type (hole) conductivity (i.e., an “NPN” design). An n-type MOSFET turns on when the bias voltage is applied to the gate electrode that is sufficient to create a conductive n-type inversion layer in the p-type channel region, thereby electrically connecting the n-type source and drain regions and allowing for majority carrier conduction therebetween. A p-type MOSFET has a “PNP” design (i.e., p-type source and drain regions and an n-type channel region) and turns on when the bias voltage is applied to the gate electrode is sufficient to create a conductive p-type inversion layer in the n-type channel region to electrically connect the p-type source and drain regions. Herein, the terms “first conductivity type” and “second conductivity type” may be used to indicate either n-type or p-type, where the first and second conductivity types are different. Thus, if a first region of a device has a first conductivity type and a second region of the device has a second conductivity type, this means either that the first region has n-type conductivity and the second region has p-type conductivity or, alternatively, that first region has p-type conductivity and the second region has n-type conductivity.

Because the gate electrode of a MOSFET is insulated from the channel region by the gate oxide layer, minimal gate current is required to maintain the MOSFET in its on-state or to switch the MOSFET between its off-state and its on-state. The gate current is kept small during switching because the gate forms a capacitor with the channel region. Thus, only minimal charging and discharging current is required during switching, allowing for less complex gate drive circuitry and faster switching speeds. MOSFETs may be stand-alone devices or may be combined with other circuit devices. For example, an insulated gate bipolar transistor (“IGBT”) is a semiconductor device that includes both a MOSFET and a bipolar junction transistor (“BJT”) that combines the high impedance gate electrode of the MOSFET with the small on-state conduction losses that may be provided by a BJT. An IGBT may be implemented, for example, as a Darlington pair that includes a high voltage n-channel MOSFET at the input and a BJT at the output. The base current of the BJT is supplied through the channel of the MOSFET, thereby allowing a simplified external drive circuit (since the drive circuit only charges and discharges the gate electrode of the MOSFET).

In some applications, MOSFETs may need to carry large currents and/or be capable of blocking high voltages. Such MOSFETs are often referred to as “power” MOSFETs. Power MOSFETs are often fabricated from wide band-gap semiconductor materials (herein, the term “wide band-gap semiconductor” encompasses any semiconductor having a band-gap of at least 1.4 electron volts (eV)). Power semiconductor devices are often formed in silicon carbide, which has a number of advantageous characteristics including, but not limited to, a high electric field breakdown strength, high thermal conductivity, high electron mobility, high melting point and high-saturated electron drift velocity.

Power semiconductor devices such as power MOSFETs can have a lateral structure or a vertical structure. In a device having a lateral structure, the terminals of the device (e.g., the drain, gate and source terminals for a power MOSFET) are on the same major surface (i.e., top or bottom) of a semiconductor layer structure, and current conduction in the device is primarily lateral (i.e., horizontal). In contrast, in a device having a vertical structure, at least one terminal is provided on each opposing major surface of the semiconductor layer structure (e.g., in a vertical MOSFET, the source and gate may be on the top surface of the semiconductor layer structure and the drain may be on the bottom surface of the semiconductor layer structure), and current conduction in the device is primarily vertical. The semiconductor layer structure may or may not include an underlying substrate such as a growth substrate.

The semiconductor layer structure of a power semiconductor device typically includes an “active region” in which one or more functional semiconductor devices are formed. The active region acts as a main junction for blocking voltage during reverse bias (off-state) operation and for providing current flow during forward bias (on-state) operation. The power semiconductor device may also have an edge termination structure such as guard rings or a junction termination extension (JTE) in a termination region of the semiconductor layer structure that is adjacent (and typically surrounding) the active region. The edge termination structure may, among other things, reduce electric field crowding effects that can occur at the outer edges (i.e., periphery) of a power semiconductor device. Typically, multiple power semiconductor devices are formed in/on a common wafer, and each power semiconductor device will typically have its own edge termination structure. After the wafer is fully processed, the resultant structure may be diced to separate (i.e., singulate) the individual edge-terminated power semiconductor devices. Each power semiconductor device may have a unit cell structure in which the active region of each power semiconductor device includes a plurality of individual “unit cell” devices that are electrically connected in parallel and that together function as a single power semiconductor device.

Vertical power semiconductor devices that include a MOSFET can have a planar gate electrode design in which the gate electrode of the transistor is formed on top of the semiconductor layer structure or, alternatively, may have the gate electrode in a gate trench within the semiconductor layer structure, which are typically referred to as gate trench MOSFETs. With the planar gate electrode design, the channel region of each unit cell transistor is horizontally disposed underneath the gate electrode. In contrast, in the gate trench MOSFET design, the channels are typically vertically disposed adjacent sidewalls of the gate electrodes. Gate trench MOSFETs may provide enhanced performance, but typically require a more complicated manufacturing process.

One failure mechanism for a power MOSFET is the so-called “breakdown” of the gate oxide layer. The gate oxide layer is subjected to high electric fields during normal device operation. The stress on the gate oxide layer caused by these electric fields generates defects in the oxide material, and these defects may build up over time. When the concentration of defects reaches a critical value, a so-called “percolation path” may be created through the gate oxide layer that electrically connects the gate electrode to the source or drain region, thereby creating a short-circuit that can destroy the device. The “lifetime” of a gate oxide layer (i.e., how long the device can be operated before breakdown occurs) is a function of, among other things, the magnitude of the electric field that the gate oxide layer is subjected to and the length of time for which the electric field is applied.

FIG. 1 is a schematic graph illustrating the relationship between the operating time until breakdown occurs (the “gate oxide lifetime”) and the level of the electric field applied to the gate oxide layer. This graph assumes that the same electric field is always applied (which is not necessarily the case). As shown in FIG. 1, the relationship may, in some cases, be generally linear when the gate oxide lifetime is plotted on a logarithmic scale. The important point to take from FIG. 1 is that as the electric field level is increased, the lifetime of the gate oxide layer decreases exponentially.

The lifetime of the gate oxide layer may be increased by increasing the thickness of the gate oxide layer, but various performance parameters of a MOSFET may be a function of the thickness of the gate oxide layer and thus increasing the thickness of the gate oxide layer is typically not an acceptable way of increasing the lifetime of the gate oxide layer.

### SUMMARY

The present invention, as manifested in one or more embodiments, is directed generally to semiconductor devices that comprise a silicon carbide based semiconductor layer structure including a drift region of a first conductivity type, a well region of a second conductivity type on the drift region, and a source region of the first conductivity type on the well region. The semiconductor devices further comprise a gate trench in the semiconductor layer structure, the gate trench extending in a first direction parallel to an upper surface of the semiconductor layer structure, and a trench shielding region in the semiconductor layer structure beneath a bottom of the gate trench. The gate trench includes a first portion having a uniform width in a third direction, parallel to the upper surface of the semiconductor layer structure and perpendicular to the first direction, at a first depth in a second direction perpendicular to the upper surface of the semiconductor layer structure and a second portion having a non-uniform width in the third direction at the first depth.

In accordance with another embodiment, a semiconductor device includes a

semiconductor layer structure comprising a drift region, a gate trench in the semiconductor layer structure, the gate trench extending in a first direction parallel to an upper surface of the semiconductor layer structure, and a trench shielding region in the semiconductor layer structure beneath a bottom of the gate trench. The trench shielding region includes a first portion having a uniform width in a third direction, parallel to the upper surface of the semiconductor layer structure and perpendicular to the first direction, at a first depth in a second direction perpendicular to the upper surface of the semiconductor layer structure and a second portion having a non-uniform width in the third direction at the first depth in the second direction.

In accordance with another embodiment, a semiconductor device includes a semiconductor layer structure comprising a drift region of a first conductivity type, a well region of a second conductivity type on the drift region, and a source region of the first conductivity type on the well region. The semiconductor device further includes a gate trench in the semiconductor layer structure, the gate trench having a longitudinal axis that extends in a first direction, a trench shielding region extending in the first direction in the semiconductor layer structure beneath a bottom of the gate trench, and at least one conductive tap in the semiconductor layer structure that electrically connects the trench shielding region to the source region. The trench shielding region includes a preferential breakdown region proximate the at least one conductive tap.

In accordance with another embodiment, a semiconductor device includes a semiconductor layer structure comprising a drift region having a first conductivity type, a JFET region in an upper portion of the JFET region that has a higher doping concentration of first conductivity dopants than the remainder of the drift region, and a well region having a second conductivity type on the drift region. The semiconductor device further includes a gate trench in the semiconductor layer structure, the gate trench extending in a first direction parallel to an upper surface of the semiconductor layer structure, a trench shielding region in the semiconductor layer structure beneath a bottom of the gate trench, and at least one conductive tap extending in the semiconductor layer structure in a second direction perpendicular to the upper surface of the semiconductor layer structure and electrically connecting the well region to the trench shielding region. The JFET region includes a first region having a first doping concentration level and a second region adjacent the first region in the first direction and having a second doping concentration level that is higher than the first doping concentration level. The conductive tap overlaps the second region of the JFET region in the second direction.

In accordance with another embodiment, a semiconductor device includes a semiconductor layer structure comprising a drift region of a first conductivity type, a gate trench in the semiconductor layer structure, the gate trench extending in a first direction parallel to an upper surface of the semiconductor layer structure, and a trench shielding region in the semiconductor layer structure beneath a bottom of the gate trench. The semiconductor device further includes a first conductive tap in the semiconductor layer structure that electrically connects the source region and the trench shielding region, and a second conductive tap in the semiconductor layer structure that electrically connects the source region and the trench shielding region. The gate trench includes a first portion, a second portion and a third portion. The first conductive tap intersects the second portion of the gate trench, the second conductive tap intersects the third portion of the gate trench, and the first portion of the gate trench is in between the second and third portions of the gate trench. At least one of the second and third portions of the gate trench has an average width in a third direction parallel to the upper surface of the semiconductor layer structure and perpendicular to the first direction that is less than an average width of the first portion of the gate trench in the third direction.

In accordance with another embodiment, a method of forming a semiconductor device includes: providing a semiconductor layer structure comprising a drift region of a first conductivity type, a well region of a second conductivity type on the drift region, and a source region of the first conductivity type on the well region; providing a gate trench in the semiconductor layer structure, the gate trench extending in a first direction parallel to an upper surface of the semiconductor layer structure; and providing a trench shielding region in the semiconductor layer structure beneath a bottom of the gate trench, wherein the gate trench includes a first portion having a uniform width in a third direction, parallel to the upper surface of the semiconductor layer structure and perpendicular to the first direction, at a first depth in a second direction perpendicular to the upper surface of the semiconductor layer structure and a second portion having a non-uniform width in the third direction at the first depth.

In accordance with another embodiment, a method of forming a semiconductor device includes: providing a semiconductor layer structure comprising a drift region; providing a gate trench in the semiconductor layer structure, the gate trench extending in a first direction parallel to an upper surface of the semiconductor layer structure; and providing a trench shielding region in the semiconductor layer structure beneath a bottom of the gate trench, the trench shielding region comprising a first portion having a uniform width in a third direction, parallel to the upper surface of the semiconductor layer structure and perpendicular to the first direction, at a first depth in a second direction perpendicular to the upper surface of the semiconductor layer structure and a second portion having a non-uniform width in the third direction at the first depth in the second direction.

In accordance with another embodiment, a method of forming a semiconductor device includes: providing a semiconductor layer structure comprising a drift region of a first conductivity type, a well region of a second conductivity type on the drift region, and a source region of the first conductivity type on the well region; providing a gate trench in the semiconductor layer structure, the gate trench having a longitudinal axis that extends in a first direction; providing a trench shielding region extending in the first direction in the semiconductor layer structure beneath a bottom of the gate trench; and providing at least one conductive tap in the semiconductor layer structure that electrically connects the trench shielding region to the source region, wherein the trench shielding region includes a preferential breakdown region proximate the at least one conductive tap.

In accordance with another embodiment, a method of forming a semiconductor device includes: providing a semiconductor layer structure comprising a drift region having a first conductivity type, a JFET region in an upper portion of the JFET region that has a higher doping concentration of first conductivity dopants than the remainder of the drift region, and a well region having a second conductivity type on the drift region; providing a gate trench in the semiconductor layer structure, the gate trench extending in a first direction parallel to an upper surface of the semiconductor layer structure; providing a trench shielding region in the semiconductor layer structure beneath a bottom of the gate trench; and providing at least one conductive tap extending in the semiconductor layer structure in a second direction perpendicular to the upper surface of the semiconductor layer structure and electrically connecting the well region to the trench shielding region, wherein the JFET region comprises a first region having a first doping concentration level and a second region adjacent the first region in the first direction and having a second doping concentration level that is higher than the first doping concentration level, the at least one conductive tap overlapping the second region of the JFET region in the second direction.

In accordance with another embodiment, a method of forming a semiconductor device includes: providing a semiconductor layer structure comprising a drift region of a first conductivity type; providing a gate trench in the semiconductor layer structure, the gate trench extending in a first direction parallel to an upper surface of the semiconductor layer structure; providing a trench shielding region in the semiconductor layer structure beneath a bottom of the gate trench; providing a first conductive tap in the semiconductor layer structure that electrically connects the source region and the trench shielding region; and providing a second conductive tap in the semiconductor layer structure that electrically connects the source region and the trench shielding region. The gate trench comprises a first portion, a second portion and a third portion, where the first conductive tap intersects the second portion of the gate trench, the second conductive tap intersects the third portion of the gate trench, and the first portion of the gate trench is in between the second and third portions of the gate trench. At least one of the second and third portions of the gate trench has an average width in a third direction parallel to the upper surface of the semiconductor layer structure and perpendicular to the first direction that is less than an average width of the first portion of the gate trench in the third direction.

Techniques of the present inventive concept can provide substantial beneficial technical effects. By way of example only and without limitation, techniques according to embodiments of the present disclosure may provide one or more of the following advantages, among other benefits:
reduces cell pitch without using a support shield in the power MOSFET device and without compromising device breakdown voltage;
enables source taps providing electrical connection to a trench bottom shield to be spaced farther apart from one another, thereby improving channel density, without risking trench bottom oxide debiasing during unclamped inductive switching conditions;
easily integrates with existing power MOSFET fabrication processes without significantly increasing device fabrication complexity;
improves avalanche ruggedness of a power MOSFET by reducing the likelihood of gate oxide failure during avalanche conditions.

These and other features and advantages of the present inventive concept will become apparent from the following detailed description of illustrative embodiments thereof, which is to be read in connection with the accompanying drawings.

### BRIEF DESCRIPTION OF THE DRAWINGS

The accompanying drawings, which are included to provide a further understanding of the invention and are incorporated in and constitute a part of this application, are presented by way of example only and without limitation, wherein like reference numerals (when used) indicate corresponding elements throughout the several views, and wherein:

FIG. 1 is a semi-log graph illustrating the relationship between the lifetime of the gate oxide layer as a function of applied electric field strength;

FIG. 2 is a schematic cross-sectional view of a unit cell of a gate trench power MOSFET having support shields;

FIG. 3 is a schematic top plan view of a layout depicting at least a portion of an example silicon carbide power MOSFET that includes support shields;

FIG. 4 is a schematic top plan view depicting at least a portion of an example silicon carbide power MOSFET including gate trenches having non-uniform widths, according to one or more embodiments of the present invention;

FIGS. 5A-5C are schematic cross-sectional views depicting a portion of the power MOSFET shown in FIG. 4 taken along lines A-A′, B-B′ and C-C′, respectively;

FIGS. 6A and 6B are schematic top plan views depicting at least a portion of example silicon carbide power MOSFETs including gate trenches having non-uniform widths, according to embodiments of the present invention;

FIG. 7 is a schematic top plan view depicting at least a portion of an example silicon carbide power MOSFET including gate trenches having non-uniform widths, according to one or more embodiments of the present invention;

FIGS. 8A and 8B are schematic cross-sectional views depicting a portion of the power MOSFET shown in FIG. 7 taken along lines A-A′ and B-B′, respectively.

FIG. 9 is a schematic top plan view depicting at least a portion of an example silicon carbide power MOSFET including trench shielding regions having non-uniform widths and gate trenches having uniform widths, according to an embodiment of the present invention;

FIG. 10 is a schematic cross-sectional view depicting a portion of the power MOSFET shown in FIG. 9 taken along line A-A′; and

FIG. 11 is a schematic top plan view depicting at least a portion of an example silicon carbide power MOSFET, according to one or more embodiments of the present invention.

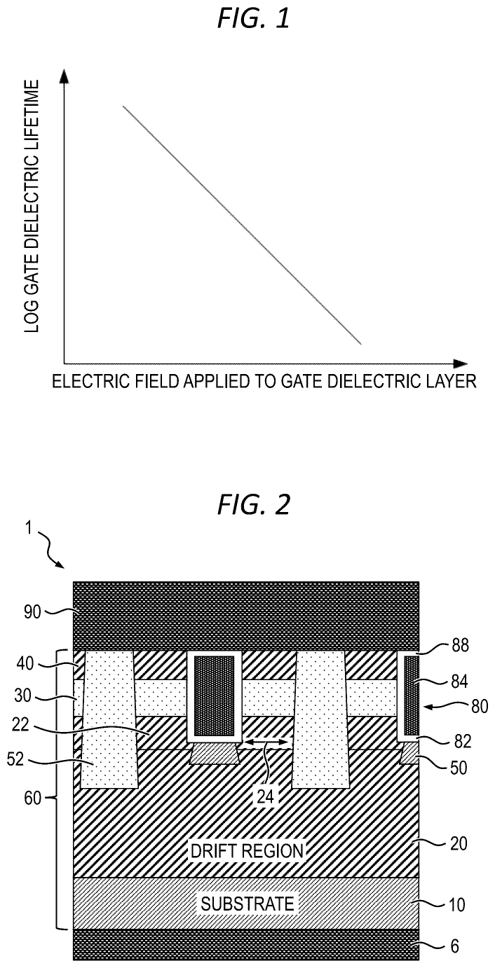

It is to be appreciated that elements in the figures may be illustrated for simplicity and clarity. Common but well-understood elements that may be useful or necessary in a commercially feasible embodiment are not necessarily shown in order to facilitate a less hindered view of the illustrated embodiments.

### DETAILED DESCRIPTION

Principles of the present inventive concept, as manifested in the embodiments disclosed herein, are described in the context of gate trench power semiconductor devices having improved avalanche robustness and increased channel density, and methods of forming such devices. It is to be appreciated, however, that the invention is not limited to the specific devices and/or methods illustratively shown and described herein. Rather, it will become apparent to those skilled in the art given the teachings herein that numerous modifications to the embodiments shown are contemplated and are within the scope of the present inventive concept. That is, no limitations with respect to the embodiments shown and described herein are intended or should be inferred.

Although the overall fabrication method and structures formed thereby as described herein are entirely novel, certain individual processing steps required to implement a portion or portions of the method(s) according to one or more embodiments of the inventive concept may utilize conventional semiconductor fabrication techniques and/or conventional semiconductor fabrication tooling. These techniques and tooling will already be familiar to one having ordinary skill in the relevant art. Moreover, many of the processing steps and tooling used to fabricate semiconductor devices are also described in a number of readily available publications, including, for example: P.H. Holloway et al., Handbook of Compound Semiconductors: Growth, Processing, Characterization, and Devices, Cambridge University Press, 2008; and R.K. Willardson et al., Processing and Properties of Compound Semiconductors, Academic Press, 2001, which are incorporated by reference herein in their entirety. It is emphasized that while some individual processing steps may be set forth herein, those steps are merely illustrative and one skilled in the art may be familiar with several equally suitable alternatives that would also fall within the scope of the present disclosure.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are contemplated. For example, a region illustrated or described as square or rectangular may have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements throughout the figures may be shown herein with common element numbers and may not be subsequently re-described.

Silicon carbide (SiC) semiconductor devices exhibit higher breakdown voltage, higher thermal conductivity, higher operating temperature, and lower losses compared to silicon (Si) based power electronic devices. Trench silicon carbide based power semiconductor devices are developed for power applications to reduce the conduction loss and switching loss compared to existing planar silicon carbide semiconductor devices. Vertical silicon carbide based power semiconductor devices that have gate trenches such as vertical power MOSFETs and IGBTs are attractive for many applications due to their inherent lower specific on-resistance, which may result in more efficient operation, particularly for power switching applications. The channels in a gate trench vertical power device are formed along sidewalls of the gate trenches, and hence are vertical channels. The carrier mobility in these vertically-oriented sidewall channels may be about 2-4 times higher than the corresponding carrier mobility in the horizontal channel of a standard planar gate (i.e., non-gate trench) vertical power device, which results in increased current density during on-state operation allowing for higher switching speeds. The gate trench design also reduces the overall pitch of the device, which increases device integration. The lower conduction losses (due to the reduced on-state resistance) and improved switching speeds make gate trench power devices particularly well-suited for high-frequency power applications having low to moderate voltage blocking requirements (e.g., about 600-1200 volts). These devices may have reduced requirements for associated passive components and require relatively simple cooling schemes. As MOSFETs are perhaps the most widely used silicon carbide based gate trench power semiconductor devices, the discussion below focuses on MOSFET embodiments. It will be appreciated, however, that each of the described embodiments may alternatively be implemented using non-oxide gate dielectric layers (e.g., nitrides, high dielectric constant materials, etc.), and that the same techniques may be used to form other gate trench power semiconductor devices such as IGBTs, gate-controlled thyristors and the like.

As discussed above, gate trench power MOSFETs are susceptible to oxide reliability issues due primarily to the presence of high electric fields in the gate oxide layers that line the bottoms and sidewalls of the gate trenches. These high electric fields degrade the gate oxide layer over time, and may eventually result in failure of the device. When gate trench MOSFETs function in reverse blocking operation (i.e., when the MOSFET is in its off-state), the source terminal of the MOSFET is typically grounded, the gate terminal is typically grounded or at a negative bias voltage, and the drain terminal is typically at a high positive voltage. During such reverse blocking operations, high electric fields extend upwardly from the drain terminal (which is on the bottom surface of the semiconductor layer structure) toward the top surface of the semiconductor layer structure. Thus, under reverse blocking operation, the bottom portion of the gate dielectric layer experiences the highest electric field levels. Due to electric field crowding effects, the electric field levels in the lower “corners” of the gate oxide layer at the bottom edges of the gate trench may be particularly high (i.e., the portions of the gate oxide layers that cover a region where the sidewalls of the gate trenches merge into the bottom of the gate trenches). Moreover, due to a difference in permittivity between silicon carbide and silicon oxide, the electric field in a silicon oxide gate oxide layer may be about 2.6 times higher than the electric field in the silicon carbide semiconductor layer structure adjacent the gate oxide layer.

Breakdown of the silicon oxide occurs when the electric field reaches a critical level. In order to avoid such breakdown, power MOSFETs may be operated with the drain voltage at lower levels during reverse blocking operation to ensure that the electrical field does not reach a level that will result in breakdown. In other words, the voltage rating of a power MOSFET may be set to ensure that premature gate oxide breakdown will not occur.

So-called “trench shielding regions” (also called “trench shields” or “bottom shields”) are often provided underneath the gate trenches of gate trench power MOSFETs in order to reduce the electric field levels in the gate oxide layer during reverse blocking operation. These trench shielding regions are formed by doping the portions of the semiconductor layer structure underneath the gate trenches with dopants having the same conductivity type as the dopants included in the channel regions of the device. The trench shielding regions are typically formed via one or more ion implantation processes in which p-type dopant ions (for an n-type MOSFET) are implanted through the bottom surfaces of the gate trenches. The trench shielding regions may, for example, extend downwardly about 0.5 to 1.0 micron (μm) or more from the bottoms of the gate trenches into the semiconductor layer structure of the device, and are moderately to highly doped regions. The trench shielding regions are electrically connected to the source terminal of the MOSFET by conductive taps having the same conductivity type as the trench shielding regions that are formed in the semiconductor layer structure. These conductive taps are also sometimes referred to as “source anchors” or as “trench shielding region connection patterns.” These conductive taps may be inside and/or outside the active region of the device. The term “connected” (or “connecting,” or like terms such as “contact” or “contacting”), as may be used herein, is intended to refer to a physical and/or electrical connection between two or more elements, and may include other intervening elements. As used herein, the term “and/or” includes any and all combinations of one or more of the associated listed items.

More recently, gate trench power MOSFETs have been suggested that include additional shielding regions that may be referred to as “support shields.” The support shields are formed in the semiconductor layer structure between adjacent gate trenches and, like the trench shielding regions, may comprise highly doped semiconductor regions having the same conductivity type as the channel regions of the MOSFET. The support shields may, for example, extend to the same depth in the semiconductor layer structure as the trench shielding regions and may be formed by a high-energy ion implantation process. The support shields may directly connect to the source metallization in the active region of the device.

FIG. 2 is a schematic cross-sectional view depicting at least a portion of an example silicon carbide power MOSFET 1 that includes support shields. The cross-sectional view of FIG. 2 shows one full unit cell of the MOSFET 1 and portions of two adjacent unit cells. As shown in FIG. 2, the MOSFET 1 includes a heavily-doped n-type (n⁺) silicon carbide semiconductor substrate 10. A lightly-doped n-type (n⁻) silicon carbide drift region 20 is provided on an upper surface of the substrate 10. An n-type silicon carbide junction field-effect transistor (JFET) region 22 is formed in an upper portion of the drift region 20. The JFET region 22 may be more heavily doped than the remainder of the drift region 20. Moderately-doped silicon carbide p-type (p) well regions 30 (also referred to as “p-wells”) are provided on an upper surface of the JFET region 22. Heavily-doped n-type (n⁺) silicon carbide source regions 40 are formed in upper portions of the p-wells 30. The substrate 10, drift region 20, p-wells 30, and source regions 40 may be considered part of a semiconductor layer structure 60 of the MOSFET 1.

In one or more embodiments, the substrate 10 may comprise, for example, a single crystal 4H silicon carbide semiconductor substrate that is heavily-doped with n-type impurities (i.e., an n+ silicon carbide substrate). The impurities may comprise, for example, nitrogen or phosphorous. In example embodiments, the n-type substrate 10 may have a doping concentration of, for example, between about 1×10¹⁸ atoms/cm³ and 1×10²¹ atoms/cm³, although other doping concentrations may be used. The substrate 10 may be relatively thick in some embodiments (e.g., about 20 μm-100 μm or more). It should be noted that while the substrate 10 is depicted as a relatively thin layer, this is done to allow enlarging the thickness of other layers and regions shown in FIG. 2, and it will be appreciated that the substrate 10 will typically have a cross-sectional thickness that is much greater than shown. The thickness of various other layers of power MOSFET 1 likewise may not be shown to scale in order to allow other portions of the devices to be enlarged in the figures for clarity of description.

In one or more embodiments, the drift region 20 may be formed via an epitaxial growth process and is doped during growth. The n-type drift region 20 may have, for example, a doping concentration of about 5×10¹⁵ atoms/cm³ to 5×10¹⁷ atoms/cm³. The drift region 20 may be a thick region, having a vertical height above the substrate 10 of, for example, about 3 μm-50 μm, and can be doped during growth. The n-type JFET region 22 may be more heavily doped than the remainder (i.e., the lower portion) of the drift region 20. The JFET region 22 may have an n-type dopant concentration of, for example, about 5×10¹⁶ atoms/cm³ to 1×10¹⁸ atoms/cm³. The JFET region 22 is generally considered to be part of the drift region 20, even though the JFET region 22 may have a different doping concentration level than the rest of the drift region 20. The drift region 20 and the substrate 10 together act as a common drain region for the power MOSFET 1.

The moderately-doped p-wells 30 formed on the upper surface of the JFET region 22 may be formed either by epitaxial growth or by implanting p-type dopant ions into the upper portion of the drift region 20 to convert the n-type upper portion of the drift region 20 into the p-wells 30. In example embodiments, the p-wells 30 may have a p-type dopant concentration of, for example, between about 5×10¹⁶ atoms/cm³ to 1×10¹⁸ atoms/cm³. The n-type source regions 40 are formed on the p-wells 30. The source regions 40 may be formed by ion implantation. The source regions 40 may have a doping concentration of, for example, between about 1×10¹⁹ atoms/cm³ and 5×10²¹ atoms/cm³.

With continued reference to FIG. 2, a plurality of gate trenches 80 are formed in the upper portion of the semiconductor layer structure 60. The semiconductor layer structure 60 also includes p-type trench shielding regions 50 that are formed underneath the respective gate trenches 80, typically by implanting p-type dopants through the bottoms of the gate trenches 80. The p-type trench shielding regions 50 extend underneath the respective gate trenches 80 for all or substantially all of the length of the gate trench 80 and may be moderately (p) or heavily doped (p⁺) silicon carbide regions. The p-type trench shielding regions 50 act to reduce the electric field levels that form in gate oxide layers (discussed below) or the trench bottom during reverse blocking operation of the MOSFET 1.

A gate oxide layer 82 is formed conformally within each gate trench 80, and gate electrodes 84 are formed in the gate trenches 80 on the gate oxide layers 82. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied. The gate electrodes 84 comprise an electrically conductive material (e.g., a metal, doped polysilicon, or the like). An intermetal dielectric pattern 88 covers the gate electrodes 84.

Although the p-type trench shielding regions 50 under the respective gate trenches 80 may shield the gate oxide layer 82 from high electric fields, they do so at the expense of creating a series of spaced-apart JFET regions that are separated from each other by the p-type trench shielding regions. Additionally, in order to prevent the bottom of the gate trenches 80 from being pulled up to a higher potential during turn-off (i.e., switching) transients and unclamped inductive switching (UIS) conditions, the p-type trench shielding regions 50 may need to be periodically anchored to the source potential (i.e., electrically connected to the source metallization 90, which is discussed below) by conductive taps. These conductive taps (not explicitly shown) need to be very frequent, thereby consuming channel density along the length of the active cell.

Alternatively or additionally, the semiconductor layer structure 60 may include p-type support shields 52 that extend downwardly from an upper portion (e.g., the upper surface) of the semiconductor layer structure 60. For example, the support shields 52 may extend vertically downward from the upper surface of the semiconductor layer structure 60, through the source regions 40 and p-wells 30, and extend vertically downward at least partially into or entirely through the JFET region 22 and into the drift region 20. Each of the gate trenches 80 may be disposed between a pair of adjacent support shields 52. The p-type support shields 52 may be moderately doped (p) or heavily doped (p⁺) silicon carbide regions. The p-type support shields 52 are connected to the source potential and are configured to break down earlier than the p-type trench shielding regions 50. A source metallization layer 90 is formed on an upper surface of the intermetal dielectric pattern 88 and on the heavily-doped source regions 40 and upper portions of the p-type support shields 52. A drain contact 6 is formed on a lower surface of the substrate 10 and serves as a drain terminal of the MOSFET 1.

The gate trenches 80 and the p-type trench shielding regions 50 thereunder may extend downwardly at least partially through the JFET region 22. As a result, the JFET region 22 may horizontally overlap the p-type support shields 52 and one or both of the gate trenches 80 and the p-type trench shielding regions 50. As used herein, two elements of a semiconductor device are considered to “horizontally overlap” if an axis that is parallel to the major surfaces of a semiconductor layer structure of the semiconductor device intersects both elements.

As shown in FIG. 2, a minimum width of the JFET region 22 between a p-type support shield 52 and an adjacent gate trench 80 (or p-type trench shielding region 50) may be referred to as a JFET gap 24. Since during on-state operation the source-to-drain current flows through these JFET gaps 24, the width of the JFET gap 24 has a direct impact on the on-state resistance of the MOSFET 1, with the smaller the JFET gap 24 the higher the on-state resistance. While the on-state resistance can be improved by widening the JFET gaps 24, this increases the spacing between adjacent active cells pitch, and therefore decreases the voltage blocking and current handling capabilities if the size of MOSFET 1 is held constant. In many cases, the size of the JFET gap 24 is set to meet an on-state resistance requirement and the size of the semiconductor chip is then set to meet a blocking voltage requirement.

The provision of support shields 52 in the gate trench power MOSFET 1 may provide increased protection to the gate oxide layer 82 by preventing the electric field in the gate oxide layer 82 from reaching levels that may cause damage to the device or reliability issues (e.g., typically about 3-4 megavolts per centimeter (MV/cm) in a reverse blocking condition), and may reduce the number of conductive taps required for the trench shielding region 50. However, the support shields 52, like the conductive taps, reduce channel density by widening a “pitch” of the active cell. In particular, the pitch of a power MOSFET refers to the distance between adjacent unit cells. When support shields 52 are added to the gate trench power MOSFET 1, it may be necessary to increase the lateral spacing between adjacent gate trenches 80 to provide room for the support shields 52. Increasing the pitch reduces the integration level of the MOSFET. Adding support shields 52 to the MOSFET 1 also typically adds several processing steps (e.g., masking, ion implantation and/or mask removal steps), which increases fabrication costs. Consequently, there are tradeoffs involved in adding support shields to a gate trench power MOSFET or other power semiconductor device.

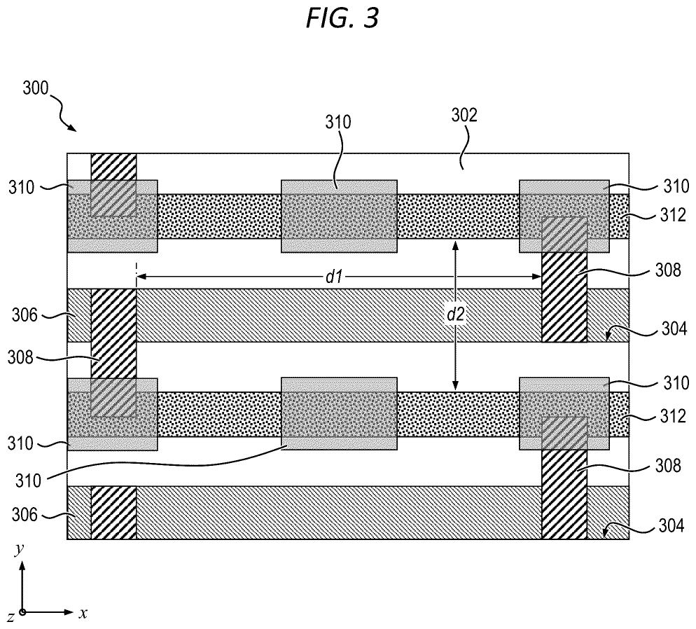

FIG. 3 is a schematic top plan view of a layout depicting at least a portion of an example silicon carbide power MOSFET 300 that includes support shields. An upper metallization layer, which is typically present in the power MOSFET for providing electrical connection to source regions in the device, is not shown for clarity purposes. This does not imply that the metallization layer is omitted in the completed MOSFET device. Referring to FIG. 3, the MOSFET 300 includes a semiconductor layer structure 302 in which a plurality of gate trenches 304 are formed. The semiconductor layer structure 302 may include a JFET region (e.g., 22 in FIG. 2), p-type wells (e.g., 30 in FIG. 2) and a source region (e.g., 40 in FIG. 2) that are sequentially stacked in a vertical direction (i.e., z direction), perpendicular to an upper surface of the semiconductor layer structure 302, on an underlying drift region (e.g., 20 in FIG. 2), as previously described in connection with the example MOSFET 1 shown in FIG. 2. The gate trenches 304 may extend vertically at least partially through the semiconductor layer structure 302. The gate trenches 304 may be arranged in a first horizontal direction (i.e., x direction) parallel to the upper surface of the semiconductor layer structure 302, and are spaced apart from one another in a second horizontal direction (i.e., y direction) parallel to the upper surface of the semiconductor layer structure 302 and intersecting the first horizontal direction. Accordingly, longitudinal axes of the gate trenches 304 extend in the x direction.

P-type trench shielding regions 306 may be formed beneath a bottom of the gate trenches 304. As previously stated, in order to prevent the trench bottom from being biased to a higher potential during turn-off (i.e., switching) transients and UIS conditions, the shielding regions 306 are anchored to source potential via a plurality of conductive taps 308 that are electrically connected to source regions in the MOSFET 300 using p-type ohmic (i.e., electrically conductive) contacts 310. The conductive taps 308 extend vertically from the upper surface of the semiconductor layer structure 302 to the trench shielding regions 306 and are provided along the trench shielding regions 306, arranged in the x direction, at periodic intervals. For example, a distance d1 between adjacent conductive taps 308 may be about 5 microns (μm)-200 μm, although embodiments are not limited thereto. In some embodiments, the distance d1 is about 20 microns (μm), which will consume about 5 percent ( 1/20) of the channel area.

The MOSFET 300 may further include a plurality of p-type support shields 312. The support shields 312 may extend vertically (z direction) through the source regions (e.g., 40 in FIG. 2), the p-wells (e.g., 30 in FIG. 2) and the JFET regions (e.g., 22 in FIG. 2) into the underlying drift region (e.g., 20 in FIG. 2). The support shields 312 may be arranged in the x direction, parallel to the gate trenches 304, and are spaced apart from one another in the y direction. For example, a distance d2 between adjacent support shields 312 may be about 2 μm-5 μm, although the distance d2 in practice may depend on parameters of the fabrication facility. In some embodiments, assuming a minimum critical dimension (CD) of about 0.3 μm, the distance d2 may be about 2 μm. Like the conductive taps 308, the support shields 312 are electrically connected to source potential using corresponding ohmic contacts 310. As previously explained, although the support shields 312 may reduce the number of conductive taps 308 required for the trench shielding regions 306, the support shields 312 reduce channel density by widening the pitch between adjacent active cells, which reduces the current handling capabilities of the MOSFET 300 if the size of MOSFET 300 is held constant.

Pursuant to embodiments of the present invention, gate trench silicon carbide power MOSFETs (and other power semiconductor devices) are provided having a non-uniform gate trench width (when viewed in plan view). Since the trench shielding regions that extend underneath the gate trenches are typically formed by implanting ions into the gate trenches, the MOSFETs (and other power semiconductor devices) according to embodiments of the present invention may have trench shielding regions that have non-uniform widths (when viewed in plan view). Configuring the gate trenches and trench shielding regions in accordance with embodiments of the invention creates preferential breakdown regions (e.g., breakdown points) in the trench shielding regions, where these preferential breakdown regions are close to the conductive taps. The term “preferential breakdown region,” as may be used herein, is intended to broadly refer to a region in the semiconductor layer structure in which current generated during transient switching and/or UIS events is directed to flow. Consequently, UIS currents will primarily only flow very close to the conductive taps, thereby preventing the trench shielding regions from being biased up to a higher potential during transient switching and UIS conditions. Providing gate trenches having non-uniform widths according to embodiments of the invention allows the support shields, that may otherwise be required in standard MOSFET designs, to be eliminated, thereby increasing channel density by allowing a reduction in pitch between adjacent active cells.

While embodiments of the present invention include both gate trenches and trench shielding regions that have non-uniform widths, it will be appreciated that in other cases only the trench shielding regions may have non-uniform widths, and the gate trenches may have uniform widths. It will also be appreciated that other techniques may be used to create preferential breakdown regions in the trench shielding regions that are near the conductive taps (e.g., doping the JFET region adjacent the conductive taps more highly compared to other portions of the drift region).

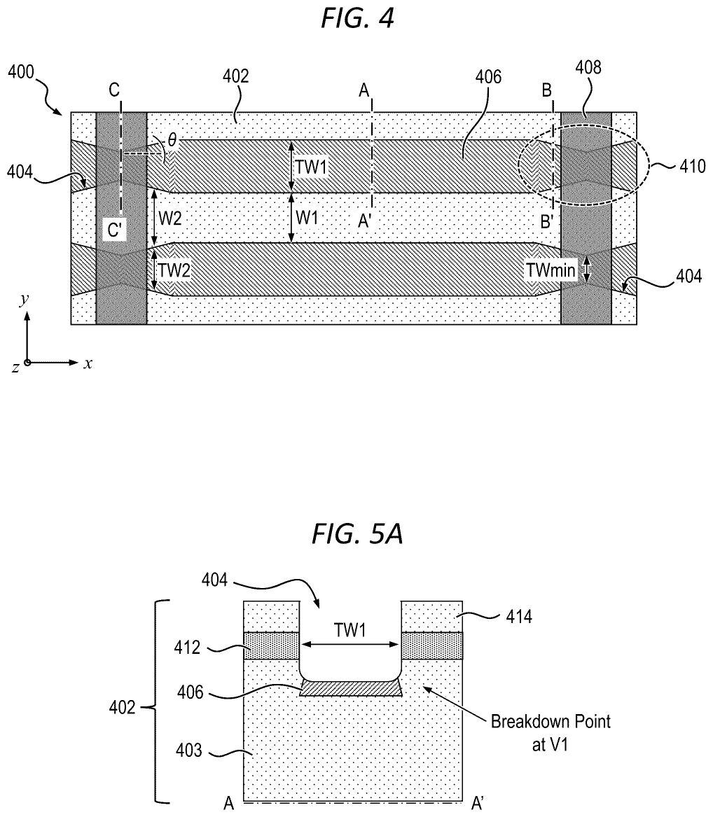

Non-limiting embodiments of the present invention will now be described in more detail with particular reference to FIGS. 4-8B. It will be appreciated that various features of the present inventive concept are described below with respect to specific examples, but that these features may be added to other embodiments and/or used in place of example features of other embodiments to provide many additional embodiments. Thus, the present invention should be understood to encompass these different combinations. Although embodiments of the invention are described herein with reference to silicon carbide semiconductor material, it will be appreciated that aspects of the present disclosure are similarly applicable to power semiconductor devices that employ other semiconductor materials, such as, for example, gallium (III) oxide (Ga₂O₃). Additionally, while the illustrative embodiments described herein may be directed to MOSFET implementations, it will be appreciated that the same techniques may be used in other gate trench power semiconductor devices such as, for example, insulated gate bipolar transistors (IGBTs), gate-controlled thyristors, and the like.

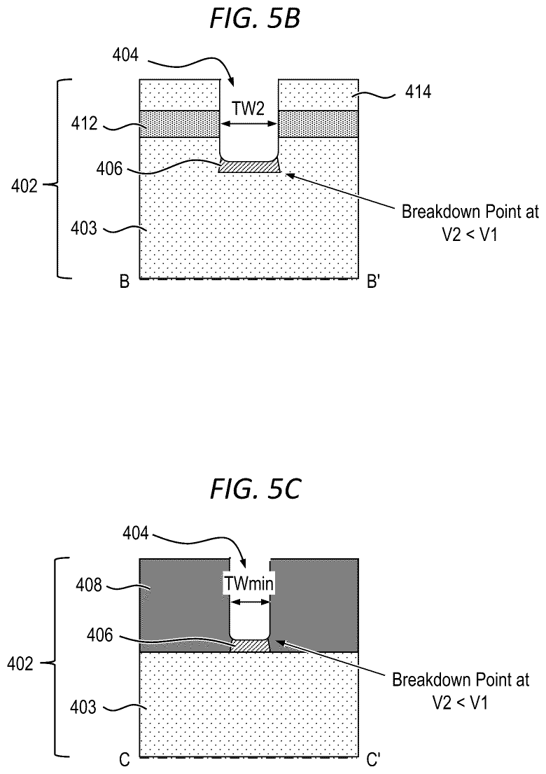

FIG. 4 is a schematic top plan view depicting at least a portion of an example silicon carbide power MOSFET 400 including gate trenches and trench shielding regions that have non-uniform widths, according to embodiments of the invention. FIGS. 5A-5C are schematic cross-sectional views depicting a portion of the power MOSFET 400 shown in FIG. 4 taken along lines A-A′, B-B′ and C-C′, respectively. Referring collectively to FIGS. 4 and 5A-5C, the power MOSFET 400 according to one or more embodiments of the invention includes a semiconductor layer structure 402 in which a plurality of gate trenches 404 having a non-uniform width are provided.

The semiconductor layer structure 402 may include a substrate (not separately shown) and a drift region 403 on the substrate. The substrate may be doped with an n-type dopant (e.g., arsenic (As) or phosphorous (P)) at a prescribed doping concentration level, and the drift region 403 may be doped with an n-type dopant at a doping concentration level that is lower compared to that of the substrate; that is, the substrate may be more heavily doped than the drift region 403. The semiconductor layer structure 402 may further include a JFET region (e.g., n-type) formed in an upper portion of the drift region 403 that is more heavily doped than the remainder of the drift region 403, well implants 412 that are moderately-doped with an impurity type of opposite conductivity to that of the JFET region (e.g., p-wells) provided on an upper surface of the JFET region, and source regions 414 that are heavily-doped with an impurity opposite to that of the well implants 412 formed in upper portions of the well implants 412. The substrate, drift region 403, JFET region, well implants 412, and source regions 414, which may be sequentially stacked in the vertical direction (i.e., z direction), may be considered part of the semiconductor layer structure 402 of the power MOSFET 400.

The gate trenches 404 extend into the semiconductor layer structure 402. The gate trenches 404 may be arranged in a first horizontal direction (i.e., x direction), parallel to an upper surface of the semiconductor layer structure 402, and are spaced apart from one another in a second horizontal direction (i.e., y direction), parallel to the upper surface of the semiconductor layer structure 402 and intersecting (e.g., perpendicular to) the first horizontal direction. Longitudinal axes of the gate trenches 404 extend in the x direction. Trench shielding regions 406 may be formed beneath the respective gate trenches 404 (e.g., proximate bottoms of the gate trenches 404), typically by implanting dopants (e.g., p-type dopants) through the bottoms of the respective gate trenches 404. In this manner, the trench shielding regions 406 overlap the gate trenches 404 in the vertical direction (i.e., z direction). The trench shielding regions 406 may extend underneath the respective gate trenches 404 for all or substantially all of the length of the gate trench 404 in the first horizonal direction and may be moderately or heavily doped silicon carbide regions having a conductivity type opposite to that of the drift region (e.g., p-type, for an n-type drift region). As previously stated in connection with FIG. 2, the trench shielding regions 404, which may be considered part of the semiconductor layer structure 402, are configured to reduce the electric field levels that form in gate oxide layers or the trench bottom during reverse blocking operation of the MOSFET 400.

As shown best in FIGS. 4 and 5C, the power MOSFET 400 further includes a plurality of conductive taps 408 (i.e., source anchors) electrically connected to the source regions in the power MOSFET 400, for example via ohmic (i.e., electrically conductive) contacts (not explicitly shown). The conductive taps 408 extend vertically (i.e., in the z direction) from the upper surface of the semiconductor layer structure 402 to the trench shielding regions 406, proximate the bottoms of the trenches 404, and are provided along the trench shielding regions 406 at periodic intervals in the x direction. These conductive taps 408 provide electrical paths for current flow during switching transients and UIS conditions. The conductive taps 408 may extend in the semiconductor layer structure 402 as stripes extending in the y direction in example embodiments.

A first portion (i.e., uniform or constant width portion) of each of the gate trenches 404 extending between adjacent conductive taps 408 in the x direction may have a first width, TW1, in the y direction that is substantially constant. A second portion (i.e., end portions) of each of the gate trenches 404 may be configured having a non-uniform width. Specifically, a width, TW2, of the second portion of each of the gate trenches 404 narrows (e.g., tapers) in the y direction as the gate trench 404 extends in the x direction from an end of the first (i.e., uniform width) portion toward the conductive taps 408; that is, all instances of the second width TW2 may be less than the first width TW1. In other cases, an average of the second widths TW2 may be less than the first width TW1. The area where ends of the second portions of two adjacent gate trenches 404 meet in the x direction and are aligned in the y direction is represented by non-uniform region 410 in FIG. 4. Thus, in accordance with embodiments of the invention, the power MOSFET 400 includes gate trenches 404 having a non-uniform width in the y direction proximate the conductive taps 408.

It is to be appreciated that the beginning of the non-uniform portion of the gate trenches 404 (i.e., the location where the uniform portion of the gate trench 404 abuts the non-uniform portion of the gate trench 404 in the x direction) may be independent of the position of the conductive taps 408 in the x direction. Furthermore, a minimum width in the y direction of the non-uniform region 410 may not necessarily overlap the conductive tap 408 in the vertical direction (z direction). The distance from the conductive tap 408 that the tapering of the second portion of the gate trench 404 begins will determine an angle θ (i.e., slope) of the tapered portion of the gate trench 404. The lower the angle θ (i.e., the smaller the slope), the longer the tapered portion of the gate trench 404 is needed to achieve the same UIS effect. If the tapered portion of the gate trench 404 is too long, and thus the angle θ too small, a desired UIS impact may not be achieved. Alternatively, if the tapered portion of the gate trench 404 is too short, and thus the angle θ too large, early breakdown in the tapered portion of the gate trench 404 may occur.

Since the trench shielding regions 406 beneath the bottom of the gate trenches 404 may be implanted through the trench bottom as previously described, a width of the trench shielding regions 406 in the y direction will also narrow proximate the conductive taps 408; that is, the lateral width of the trench shielding regions 406 will follow a contour of sidewalls of the gate trenches 404. With the gate trenches 404 narrowing near the conductive taps 408 of the underlying trench shielding regions 406, a JFET region of the semiconductor layer structure 402 between adjacent gate trenches 404 in the y direction will have a first width W1 in a region near a mid-point of the gate trenches (e.g., near line A-A′), away from the conductive taps 408, that is less than a second width W2 in a region at or near the conductive taps 408 (e.g., near line B-B′); that is, the power MOSFET 400 will have a wider JFET region, in cross-section, at a point of electrical connection with the conductive taps 408, while the remaining JFET region outside of the conductive taps 408 and between adjacent gate trenches 404 will have a narrower cross-sectional width.

It is to be appreciated that since the trench shielding regions 406 may have a horizontal width (e.g., in the y direction) that varies as a function of the cross-sectional thickness of the trench shielding regions 406 in the z direction (e.g., the trench shielding regions 406 may have a cross-section that is trapezoidal in shape, as shown in FIGS. 5A and 5B), the width of the trench shielding regions 406 may be determined at a prescribed depth in the z direction as a reference point. For example, the width of the trench shielding regions 406 may be defined at an upper surface of the trench shielding regions 406, or at a middle depth in the z direction of the trench shielding regions 406, or at a bottom surface of the trench shielding regions 406, although embodiments are not limited thereto.

For the illustrative embodiment shown in FIGS. 4, 5A and 5B, the non-uniform region 410 encompassing the tapered ends (i.e., non-uniform width portion) of the gate trenches 404 of two consecutive active cells arranged in the x direction may be configured in the shape of a bow-tie when viewed in plan view, although embodiments are not limited to any specific shape or dimensions. More particularly, the width in the y direction of ends of the second portions of each of the gate trenches 404 disposed outside and near the conductive taps 408 (i.e., non-overlapping with respect to the conductive taps 408) in the x direction, may be the same as the width TW1 of the uniform width portion of the gate trenches 404. As each gate trench 404 extends in the x direction toward a corresponding one of the conductive taps 408, the width of the gate trench 404 in the y direction will decrease linearly, reaching a minimum width, TWmin, in an area where the conductive tap 408 vertically overlaps the gate trench 404 (e.g., a midline, at line C-C′, of the conductive taps 408 in the y direction). The term “vertically overlaps” (or “vertically overlapping,” or like terms), as may be used herein, is intended to broadly refer to a first element that intersects with at least a portion of a second element in the vertical direction (i.e., the z direction), but does not require that the first and second elements be completely aligned with one another in a horizontal plane (i.e., in the x direction and/or the y direction). As the gate trench 404 of an adjacent active cell extends from its minimum width away from the conductive tap 408 in the x direction, the width of the gate trench 404 in the y direction may increase linearly until it reaches the width TW1 of the first (uniform width) portion of the gate trench 404 of the adjacent active cell.

In one or more embodiments, the first width TW1 of the gate trenches 404 at or near a middle region of the gate trenches 404 (e.g., line A-A′) may be about 1.0 μm-1.2 μm, and a spacing between adjacent gate trenches 404 (i.e., pitch) in the y direction may be about 3.0 μm-3.5 μm, although embodiments are not limited thereto. The minimum second width TW2 in the y direction of the gate trenches 404 may be about 0.1 μm-0.5 μm narrower than the first width TW1, and more preferably about 0.1 μm-0.3 μm narrower than the first width TW1 or about 0.1 μm-0.25 μm narrower than the first width TW1, although embodiments are not limited thereto.

A wider JFET region at line B-B′ will lead to more two-dimensional electric field concentration near bottom corners of the trench shielding regions 406 under the bottom of the gate trenches 404 during reverse blocking operation, and so earlier avalanche breakdown will occur at the bottom corners of the trench shielding regions 406 closer to the conductive taps 408 (at line B-B′) compared to the bottom corners of the trench shielding regions 406 away from the conductive taps 408, where the JFET region is narrower (e.g., at line A-A′). That is, a breakdown voltage V2 of the trench shielding regions 406 near the conductive taps 408 will be less than a breakdown voltage V1 of the trench shielding regions 406 near a midpoint of the gate trenches 404. Therefore, the UIS current will tend to primarily flow through the trench shielding regions 406 at line B-B′ and into the conductive taps 408. Consequently, since this configuration according to embodiments of the invention does not result in significant UIS current flowing through a substantial length of the trench shielding regions 406, the trench shielding regions 406 will not be biased to a higher potential during transient switching or UIS events, thereby protecting the gate oxide layer (e.g., 82 in FIG. 2) at the bottom of the gate trenches 404. This arrangement of the gate trenches 404 having non-uniform widths according to embodiments of the invention also enables adjacent conductive taps 408 to be spaced farther apart in the x direction, thereby improving channel density, without risking debiasing the gate trench bottom during UIS conditions, since UIS current will preferentially pass through regions close to the conductive taps 408 where the electric field is enhanced.

Configuring the gate trenches 404, and hence the underlying trench shielding regions 406, to have tapered ends means that the trench width in the active cell may not necessarily be at the minimum dimension that the technology supports. Therefore, widening the gate trenches 404 more than the minimum width allowed by the technology may be a trade-off to directing UIS current to desired locations in the active cell. However, it may be sufficient to widen the gate trenches 404 by as little as about 0.1 μm to achieve the desired advantages, which results in significantly less increase in active cell pitch compared to the increase in active cell pitch resulting from the inclusion of support shields (e.g., 52 in FIG. 2) in the MOSFET.

As previously described, the end portions of each of the gate trenches 404 in the power MOSFET 400 shown in FIGS. 4, 5A and 5B are configured having opposing sidewalls that taper linearly inward in the y direction, so that the width (e.g., TW2) of the gate trenches 404 proximate to the conductive taps 408 is less than the width (e.g., TW1) outside of the conductive taps 408. In one or more other embodiments, end portions of the gate trenches 404 in the non-uniform width region 410 of the power MOSFET 400 may be configured having widths that decrease nonlinearly.

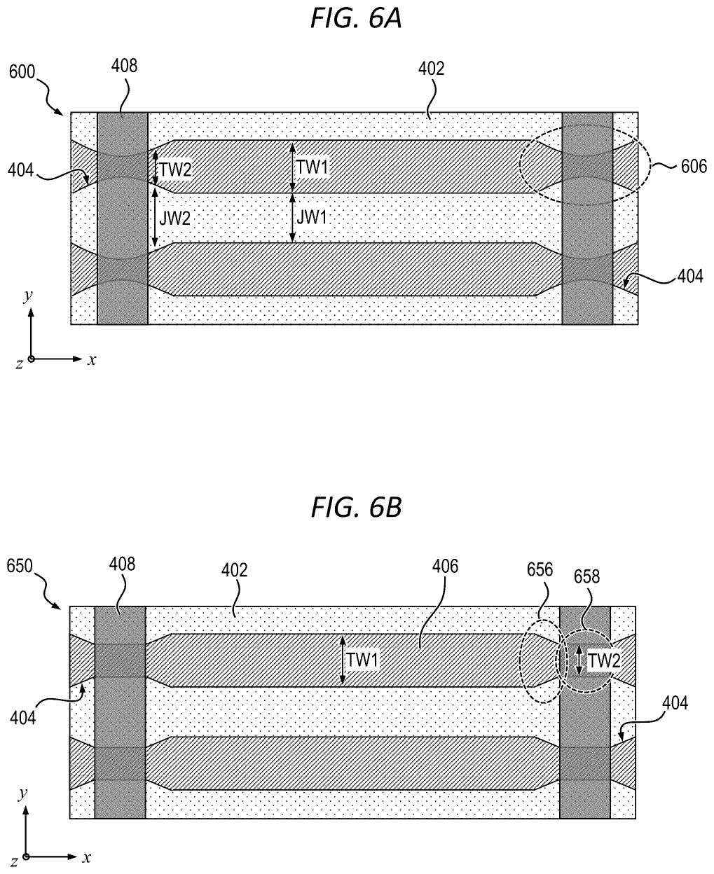

By way of example only and without limitation or loss of generality, FIGS. 6A and 6B are schematic top plan views depicting at least a portion of example silicon carbide power MOSFETs including gate trenches having non-uniform widths, according to embodiments of the invention. Like reference numbers represent like elements throughout. Referring to FIG. 6A, a power MOSFET 600 according to one or more embodiments includes a plurality of gate trenches 404 formed in the semiconductor layer structure 402. Each of at least a subset of the gate trenches 404 includes end portions disposed near corresponding conductive taps 408 that have a (varying) width TW2 in the y direction that is less than the width TW1 of the gate trenches 404 in the uniform width portion thereof (i.e., the portion of the gate trenches 404 that extends between adjacent conductive taps 408 in the x direction having a substantially constant width in the y direction). A non-uniform width region 606 of the gate trenches 404 proximate to the conductive taps 408 depicts end portions of the gate trenches 404 that are configured having curved sidewalls, rather than linearly tapered sidewalls as in the power MOSFET 400 shown in FIG. 4. Specifically, opposing sidewalls of the end portions of the gate trenches 404 are configured having an inward curve (i.e., a concave shape), whereby a width of the gate trenches 404 decreases nonlinearly proximate to an area vertically overlapped by the conductive taps 408.

With the end portions of the gate trenches 404 configured in this manner, the JFET region between adjacent gate trenches 404 in the y direction defined by the end portions of the gate trenches 404 proximate the conductive taps 408 will have a convex shape, whereby the width W2 of the JFET region of the semiconductor layer structure 402 near the conductive taps 408 is greater than the width W1 of the JFET region farther outside of the conductive taps 408 in the x direction (i.e., between the uniform width portions of adjacent gate trenches 404 in the y direction). It will be appreciated that various shapes and dimensions of the gate trenches 404 may be used that are similarly configured to direct transient switching and/or UIS currents toward the conductive taps 408, so as to protect the gate trench oxide near the bottom of the gate trenches 404 from breakdown by preventing debiasing of the gate trench oxide during transient switching or UIS events. As one additional example, opposing sidewalls of the end portions of the gate trenches 404 may be configured to have outwardly curved shapes (i.e., a convex shapes).

Referring to FIG. 6B, a power MOSFET 650 according to one or more embodiments includes a plurality of gate trenches 404 formed in the semiconductor layer structure 402. Each of at least a subset of the gate trenches 404, like the gate trenches 404 shown in FIG. 6A, includes a first portion having a uniform width TW1 in the y direction and a second portion having a non-uniform width in the y direction. In this embodiment, the second (non-uniform) portion of the gate trenches 404 may include a first region 656 having a varying width and a second region 658 having a constant width. More particularly, a width in the y direction of the first region 656 may have a first width TW1, adjacent to the first (uniform) portion of the gate trench 404, that narrows (e.g., linearly or nonlinearly) to a second width TW2 in the y direction at an area where the conductive tap 408 contacts the gate trench 404, the second width TW2 being less than the first width TW1. The second region 658 of the second portion of the gate trench 404, which may include an area extending in the x direction where the conductive tap 408 vertically overlaps the gate trench 404, may have the constant width TW2 in the y direction. Assuming that the minimum width of the gate trench 404 (e.g., TW2) is equal to the target critical dimension (CD) of the semiconductor process technology used to fabricate the device 650, this configuration may reduce the maximum width (e.g., TW1) of the gate trench 404, thereby increasing channel density, particularly where the conductive tap 408 is as deep or deeper than the trench shielding region (e.g., 406 in FIG. 5A). In this embodiment, the width of the conductive tap 408 in the x direction may have an influence on the design of the tapered portion of the gate trenches 404 (e.g., length of the tapered portion of the gate trenches 404 in the x direction or angle of the tapered portion).

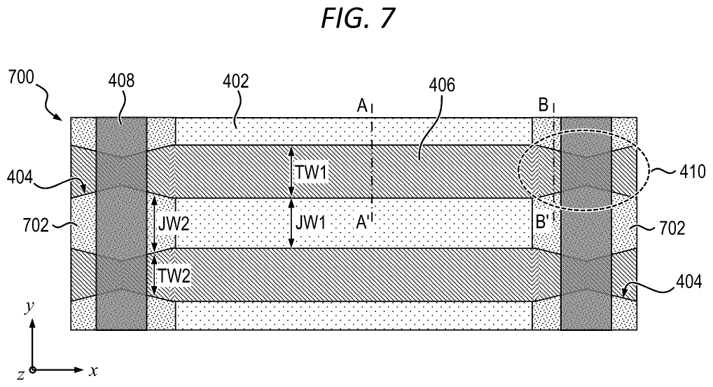

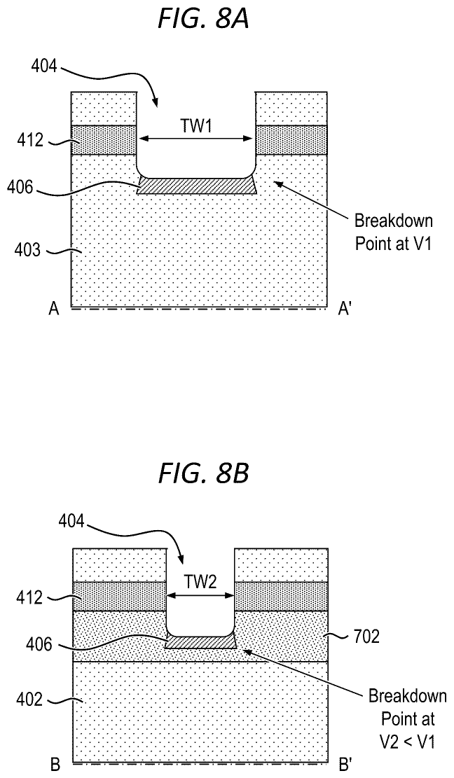

FIG. 7 is a schematic top plan view depicting at least a portion of an example silicon carbide power MOSFET 700 including gate trenches having non-uniform widths, according to one or more embodiments of the invention. FIGS. 8A and 8B are schematic cross-sectional views depicting a portion of the illustrative power MOSFET 700 shown in FIG. 7 taken along lines A-A′ and B-B′, respectively. Referring collectively to FIGS. 7, 8A and 8B, the power MOSFET 700 may be arranged in a manner consistent with the power MOSFET 400 depicted in FIG. 4. Additionally, the power MOSFET 700 may include a second n-type silicon carbide JFET region 702 disposed in the semiconductor layer structure 402 near the conductive source taps 408.

The second JFET region 702, which may be formed, for example, using an implant process (e.g., ion implantation), is doped at a higher impurity concentration compared to the JFET region (i.e., drift region) farther away from the conductive taps 408 in the x direction. The second JFET region 702 may extend beyond the edges of the conductive taps 408 in the x direction but does not extend entirely between adjacent conductive taps 408; that is, the second JFET region 702 has a width in the x direction that may vertically overlap the non-uniform region 410 where the second portions of two adjacent gate trenches 404 meet. It is to be appreciated, however, that opposing edges of the second JFET region 702 in the x direction need not be vertically aligned with a beginning of the non-uniform portion of the gate trenches 404; that is, the start of the non-uniform portion of the gate trenches 404 may be independent of the width of the second JFET region 702 in the x direction. Moreover, in some embodiments, a bottom surface of the second JFET region 702 extends vertically deeper into the semiconductor layer structure 402 than a bottom surface of the trench shielding regions 406, relative to the upper surface of semiconductor layer structure 402. The second JFET region 702, which may be more heavily doped relative to the semiconductor layer structure 402 in which the uniform width portion of the gate trenches 404 are formed, serves to concentrate the electric field near the conductive taps 408 (e.g., near line B-B′) and directs UIS current to the conductive taps to precipitate breakdown in a region proximate the conductive taps 408.

According to aspects of the inventive concept, one objective is to provide trench shielding regions (e.g., 406 in FIGS. 8A and 8B) having a non-uniform width in the y direction. As previously stated, this can be achieved by providing gate trenches (e.g., 404 in FIGS. 8A and 8B) having a non-uniform width in the y direction and then implanting the trench shielding regions through the bottom of the gate trenches. In this manner, the width of the trench shielding regions will follow a profile (i.e., contour) of the bottom of the gate trenches in the y direction (i.e., in plan view). It is to be appreciated, however, that in some embodiments, trench shielding regions having a non-uniform width in the y direction may be provided using gate trenches having a uniform width in the y direction; that is, the trench shielding regions may not necessarily match a profile of the bottom of the gate trenches in plan view.

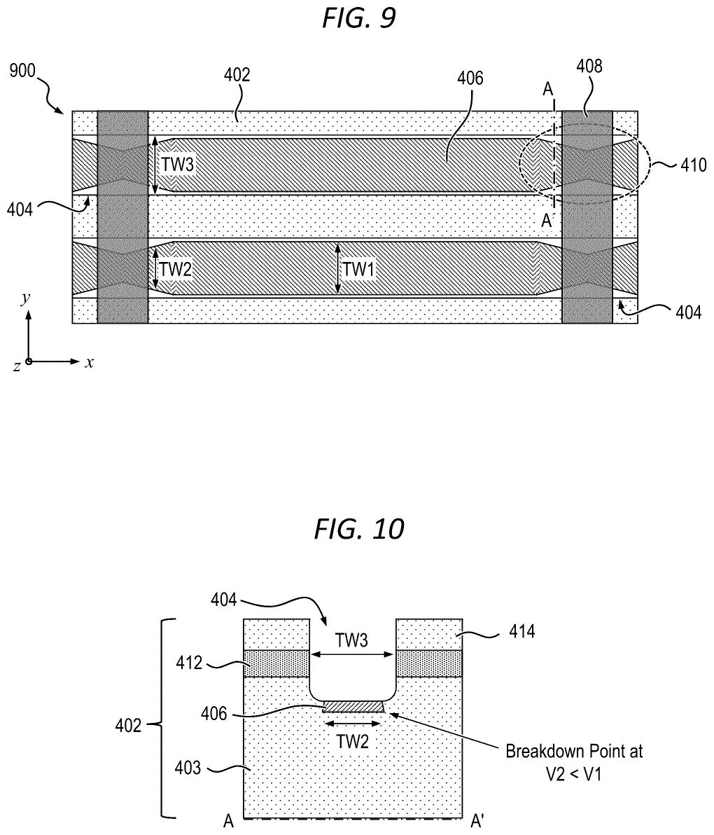

By way of example only and without limitation, FIG. 9 is a schematic top plan view depicting at least a portion of an example silicon carbide power MOSFET 900 including gate trenches having a uniform width and trench shielding region having a non-uniform width, according to one or more embodiments of the invention. FIG. 10 is a schematic cross-sectional view depicting a portion of the illustrative power MOSFET 900 shown in FIG. 9 taken along line A-A′.

Referring to FIGS. 9 and 10, the power MOSFET 900 may be arranged in a manner consistent with the illustrative power MOSFET 400 depicted in FIG. 4. In this embodiment, however, the trench shielding regions 406 may have a non-uniform width in the y direction and the gate trenches 404 may have a uniform (i.e., constant) width in the y direction for the entire distance in the x direction between adjacent conductive taps 408. Specifically, the trench shielding regions 406 may be configured having a first portion with a uniform width TW1 in the y direction and a second portion with a non-uniform width in the y direction that varies (linearly or nonlinearly) from the width TW1 to a width TW2, where TW2 is less than TW1. The gate trenches 404 may be configured having a constant (i.e., uniform) width TW3 in the y direction. The width TW3 of the gate trenches 404 may be the same (or nearly the same) as the width TW1 of the first (uniform) portion of the trench shielding regions 406, although embodiments are not limited thereto.

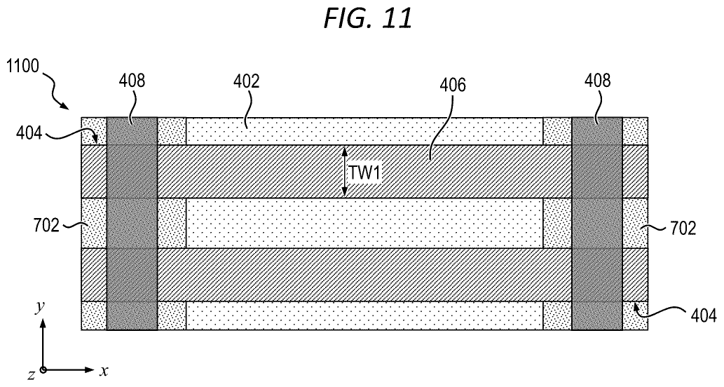

FIG. 11 is a schematic top plan view depicting at least a portion of an example silicon carbide power MOSFET 1100, according to one or more embodiments of the invention. The power MOSFET 1100 includes gate trenches 404 and trench shielding regions 406 having a uniform width in the second horizontal direction (i.e., y direction), parallel to the upper surface of the semiconductor layer structure 402. In this illustrative embodiment, each of the gate trenches 404 and the trench shielding regions 406 may have the same width TW1 in the second horizontal direction, although embodiments are not limited thereto.

The power MOSFET 1100 further includes a second JFET region 702 (e.g., n-type silicon carbide) disposed in the semiconductor layer structure 402 overlapping the conductive source taps 408 in the vertical direction (z direction). As previously described, the second JFET region 702, which may be formed, for example, using an implant process (e.g., ion implantation), is doped at a higher impurity concentration compared to the JFET region farther away from the conductive taps 408 in the x direction. The second JFET region 702 may extend beyond the conductive taps 408 in the x direction but does not extend entirely between adjacent conductive taps 408. In some embodiments, a bottom surface of the second JFET region 702 extends vertically deeper into the semiconductor layer structure 402 than a bottom surface of the trench shielding regions 406, relative to the upper surface of semiconductor layer structure 402. The second JFET region 702 serves to concentrate the electric field near the conductive taps 408 and directs UIS current to the conductive taps 408 to precipitate breakdown in a region proximate the conductive taps 408.

In the description above, each example embodiment has a certain conductivity type. It will be appreciated that opposite conductivity type devices may be formed by simply reversing the conductivity of the n-type and p-type layers in each of the above embodiments. Thus, it will be appreciated that the present invention covers both n-channel and p-channel devices for each different device structure (e.g., MOSFET, IGBT, etc.).

The present invention has primarily been discussed above with respect to silicon carbide based power semiconductor devices. It will be appreciated, however, that silicon carbide is used herein as an example and that the devices discussed herein may be formed in any appropriate wide band-gap semiconductor material system. As an example, gallium nitride based semiconductor materials (e.g., gallium nitride, aluminum gallium nitride, etc.) may be used instead of silicon carbide in any of the embodiments described above.

Embodiments of the present invention have been described above with reference to the accompanying drawings, in which embodiments of the invention are shown. It will be appreciated, however, that this invention may be embodied in many different forms and should not be construed as limited to the embodiments set forth above. Rather, these embodiments are provided so that this disclosure will be thorough and complete, and will fully convey the scope of the invention to those skilled in the art.

Herein, the term “plurality” means two or more. Herein, “substantially” means within about +/−10%.

It will be understood that, although the ordinal terms such as first, second, etc. may be used throughout this specification to describe various elements, these elements should not be limited by these terms. These terms are used merely to distinguish one element from another and are not intended to convey any particular order of the elements unless specifically stated. For example, a first element could be termed a second element, and, similarly, a second element could be termed a first element, without departing from the scope of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above,” “upper” or “lower,” “top” or “bottom,” and the like, may be used herein to describe a relationship of one element, layer or region to another element, layer or region as illustrated in the figures. It will be understood, however, that these terms are intended to encompass different orientations of the device in addition to the orientation depicted in the figures.

Embodiments of the invention are described herein with reference to plan views and cross-sectional views that are schematic illustrations of idealized embodiments (and intermediate structures) of the invention. The thickness of layers and regions depicted in the drawings may be exaggerated for clarity. Additionally, variations from the shapes of the illustrations as a result, for example, of manufacturing techniques and/or tolerances, are to be expected and are within the scope of the inventive concept.

Some embodiments of the invention are described with reference to semiconductor layers and/or regions which are characterized as having a conductivity type such as n-type or p-type, which refers to the majority carrier concentration in the layer and/or region. Thus, n-type material has a majority equilibrium concentration of negatively charged electrons, while p-type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region, and does not imply a particular polarity of the layer or region.

In the drawings and specification, there have been disclosed typical embodiments of the invention and, although specific terms are employed, they are used in a generic and descriptive sense only and not for purposes of limitation, the scope of the invention being set forth in the following claims.

1. A semiconductor device, comprising:
a semiconductor layer structure comprising a drift region of a first conductivity type, a well region of a second conductivity type on the drift region, and a source region of the first conductivity type on the well region;
a gate trench in the semiconductor layer structure, the gate trench extending in a first direction parallel to an upper surface of the semiconductor layer structure; and
a trench shielding region in the semiconductor layer structure beneath a bottom of the gate trench,
wherein the gate trench comprises a first portion having a uniform width in a third direction, parallel to the upper surface of the semiconductor layer structure and perpendicular to the first direction, at a first depth in a second direction perpendicular to the upper surface of the semiconductor layer structure and a second portion having a non-uniform width in the third direction at the first depth.

2. The semiconductor device of claim 1, further comprising at least one conductive tap extending in the semiconductor layer structure in the second direction and electrically connected to the source region and to the trench shielding region.

3. The semiconductor device of claim 2, wherein the second portion of the gate trench is proximate the at least one conductive tap.

4. The semiconductor device of claim 2, wherein the width in the third direction of the second portion of the gate trench decreases linearly from an end of the first portion of the gate trench to a region overlapped by the at least one conductive tap in the second direction.

5. The semiconductor device of claim 2, wherein the width in the third direction of the second portion of the gate trench decreases nonlinearly from an end of the first portion of the gate trench to a region overlapped by the at least one conductive tap in the second direction.

6. The semiconductor device of claim 2, wherein opposing sidewalls of the second portion of the gate trench are configured having an inward curve, whereby a width in the third direction of the gate trench decreases proximate an area vertically overlapped by the at least one conductive tap.

7. The semiconductor device of claim 2, wherein the second portion of the gate trench is disposed at an electrical connection point between the at least one conductive tap and the trench shielding region.

8. The semiconductor device of claim 1, further comprising a second JFET region adjacent the first JFET region.

9. The semiconductor device of claim 8, wherein the second JFET region overlaps the second portion of the gate trench in the second direction.

10. The semiconductor device of claim 8, wherein a bottom surface of the second JFET region extends deeper in the second direction into the semiconductor layer structure than a bottom surface of the trench shielding region, relative to the upper surface of semiconductor layer structure.

11. The semiconductor device of claim 1, wherein the trench shielding region has the second conductivity type.

12. The semiconductor device of claim 1, wherein the trench shielding region comprises a first portion having a uniform width in the third direction at a second first depth in the second direction and a second portion having a non-uniform width in the third direction at the second depth.

13. The semiconductor device of claim 1, wherein the trench shielding region has a varying width in the third direction that matches a varying width in the third direction of a bottom of the gate trench.

14. The semiconductor device of claim 1, wherein the trench shielding region overlaps the gate trench in the second direction.

15. A semiconductor device, comprising:
a semiconductor layer structure comprising a drift region;
a gate trench in the semiconductor layer structure, the gate trench extending in a first direction parallel to an upper surface of the semiconductor layer structure; and
a trench shielding region in the semiconductor layer structure beneath a bottom of the gate trench, the trench shielding region comprising a first portion having a uniform width in a third direction, parallel to the upper surface of the semiconductor layer structure and perpendicular to the first direction, at a first depth in a second direction perpendicular to the upper surface of the semiconductor layer structure and a second portion having a non-uniform width in the third direction at the first depth in the second direction.

16. The semiconductor device of claim 15, further comprising at least one conductive tap extending in the semiconductor layer structure in a second direction perpendicular to the upper surface of the semiconductor layer structure and electrically connected to the trench shielding region.

17. The semiconductor device of claim 16, wherein the second portion of the trench shielding region is proximate the at least one conductive tap.

18. The semiconductor device of claim 16, wherein the drift region is of a first conductivity type, wherein the semiconductor layer structure comprises a well region of a second conductivity type on the drift region and a source region of the first conductivity type on the well region, and wherein the trench shielding region is electrically connected to the source region via the at least one conductive tap.

19. The semiconductor device of claim 16, wherein the gate trench comprises a first portion having a uniform width in the third direction and a second portion having a non-uniform width in the third direction, and wherein the second portion of the gate trench is disposed proximate an electrical connection point between the at least one conductive tap and the trench shielding region.

20. The semiconductor device of claim 15, wherein the gate trench has a uniform width in the third direction.

21. The semiconductor device of claim 15, wherein the trench shielding region has a varying width in the third direction that matches a varying width in the third direction of the bottom of the gate trench.

22. The semiconductor device of claim 15, wherein a profile of the trench shielding region matches a profile of the bottom of the gate trench when viewed in plan view.

23. The semiconductor device of claim 15, wherein the gate trench is configured having a uniform width in the third direction.

24. The semiconductor device of claim 15, wherein the drift region comprises a first region having a first doping concentration level and a second region laterally adjacent to the first region and having a second doping concentration level that is higher than the first doping concentration level, the first portion of the trench shielding region being in the first region of the drift region and the second portion of the trench shielding region being in the second region of the drift region.

25. The semiconductor device of claim 15, wherein the trench shielding region overlaps the gate trench in the second direction.

26-49. (canceled)
